(19) United States
(12) Patent Application Publication
(10) Pub. No.: US 2025/0279266 A1
(43) Pub. Date: Sep. 4, 2025

(54) METHOD OF REMOVING ORGANOMETALLIC POLYMER FILM, PLASMA PROCESSING METHOD, AND PLASMA PROCESSING APPARATUS

(71) Applicant: Tokyo Electron Limited, Tokyo (JP)

(72) Inventors: Nobuo MATSUKI, Yamanashi (JP); Daisuke OBA, Albany, NY (US)

(21) Appl. No.: 19/058,855

(22) Filed: Feb. 20, 2025

(51) Int. Cl. H01J 37/32

(52) U.S. Cl. CPC H01J 37/32862; H01J 2237/332; H01J 2237/334

(57) ABSTRACT

A method of removing an organometallic polymer film deposited inside a processing chamber is provided. The method includes: a) supplying a first etching gas to the processing chamber, and forming the first etching gas into a plasma; and b) allowing the organometallic polymer film to react with the plasma to vaporize and remove the organometallic polymer film. The first etching gas includes a hydrogen gas, a carbon-containing gas, and a nitrogen-containing gas.

### CROSS-REFERENCE TO RELATED APPLICATIONS

This application is based on and claims priority to Japanese Patent Application No. 2024-032476 filed on Mar. 4, 2024, the contents of which are incorporated herein by reference in its entirety.

### BACKGROUND

### 1. Field of the Invention

The present disclosure relates to a method of removing an organometallic polymer film, a plasma processing method, and a plasma processing apparatus.

### 2. Description of the Related Art

A technology for removing a resist material deposited inside a processing chamber is disclosed (for example, see Japanese Unexamined Patent Application Publication No. 2022-538554).

### SUMMARY

According to one aspect of the present disclosure, a method of removing an organometallic polymer film is a method of removing an organometallic polymer film deposited inside a processing chamber. The method includes: i) supplying a first etching gas to the processing chamber, and forming the first etching gas into a plasma; and ii) allowing the organometallic polymer film to react with the plasma to vaporize and remove the organometallic polymer film. The first etching gas includes a hydrogen gas, a carbon-containing gas, and a nitrogen-containing gas.

The object and advantages of the embodiments will be realized and attained by means of the elements and combinations particularly pointed out in the claims.

It is to be understood that both the foregoing general description and the following detailed description are exemplary and explanatory and not restrictive of the invention, as claimed.

### BRIEF DESCRIPTION OF THE DRAWINGS

FIG. 1 is a cross-sectional view illustrating one example of a plasma processing apparatus according to the present embodiment;

FIG. 2 is a flowchart illustrating one example of a plasma processing method according to the present embodiment;

FIGS. 3A to 3D are cross-sectional views illustrating one example of the plasma processing method according to the present embodiment;

FIGS. 4A to 4C are cross-sectional views illustrating one example of the plasma processing method according to the present embodiment;

FIG. 5 is a diagram illustrating one example of a reaction scheme of an organometallic polymer film; and

FIG. 6 is a graph depicting a gas type dependency of an etching rate of the organometallic polymer film.

### DETAILED DESCRIPTION

Hereinafter, non-limiting embodiments of the present disclosure will be described with reference to the attached drawings. Throughout the attached drawings, the same or corresponding members or parts are designated by the same or corresponding reference symbols, and redundant description thereof will be omitted.

### [Plasma Processing Apparatus]

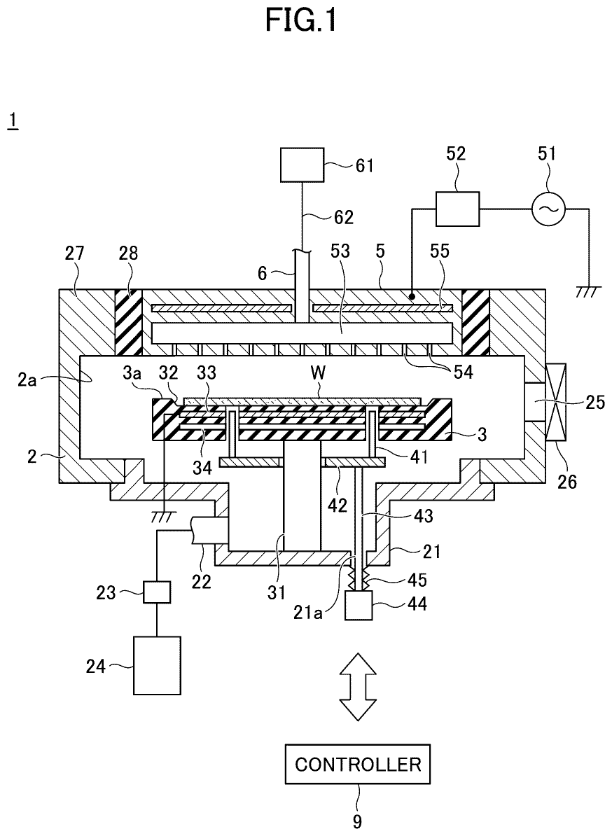

A plasma processing apparatus 1 according to the present embodiment will be described with reference to FIG. 1. FIG. 1 is a cross-sectional view illustrating one example of the plasma processing apparatus 1 according to the present embodiment. The plasma processing apparatus 1 is an example of an apparatus that forms an organometallic polymer film on a substrate W by chemical vapor deposition (CVD) using a plasma.

The plasma processing apparatus 1 includes a substantially cylindrical airtight processing chamber 2. An exhaust chamber 21 is provided at a central portion of a bottom wall of the processing chamber 2.

The exhaust chamber 21 has, for example, a substantially cylindrical shape that projects downward. An exhaust flow path 22 is coupled to the exhaust chamber 21, for example, at a side surface of the exhaust chamber 21.

An exhausting device 24 is coupled to the exhaust flow path 22 via a pressure regulator 23. The pressure regulator 23 includes, for example, a pressure adjusting valve, such as a butterfly valve. The exhausting device 24 includes, for example, a vacuum pump. The exhaust flow path 22 is configured so that the inner atmosphere of the processing chamber 2 is decompressed by the exhausting device 24. A loading port 25 is provided in a side surface of the processing chamber 2. The loading port 25 is configured to be opened and closed by a gate valve 26. The substrate W is transported in and out between the processing chamber 2 and a transfer chamber (not illustrated) through the loading port 25.

In the processing chamber 2, a stage 3 that horizontally supports the substrate W is disposed. The stage 3 is formed in a substantially circular shape in a plan view. The stage 3 is supported by a support member 31. A substantially circular recess 32, in which a substrate W having, for example, a diameter of 300 mm is to be placed, is formed in the upper surface 3a of the stage 3. The recess 32 has an inner diameter that is slightly larger (e.g., by approximately 1 mm to approximately 4 mm) than a diameter of a substrate W. The recess 32 is configured to have a depth that is, for example, substantially the same as a thickness of a substrate W. The stage 3 is formed of a ceramic material, such as aluminum nitride (AlN) or the like. The stage 3 may be formed of a metal material, such as nickel (Ni) or the like. A guide ring for guiding a substrate W may be provided at the peripheral edge of the upper surface 3a of the stage 3 instead of the recess 32.

A lower electrode 33, which is, for example, grounded, is embedded in the stage 3. A temperature controller 34 is embedded below the lower electrode 33. The temperature controller 34 adjusts a temperature of the stage 3 or the substrate W placed on the stage 3 to a set temperature according to a control signal transmitted from a controller 9. In the case where the entire stage 3 is formed of a metal, the entire stage 3 functions as a lower electrode, and therefore the lower electrode 33 may not be embedded in the stage 3. Multiple (e.g., three) lifting pins 41 for holding and lifting a substrate W placed on the stage 3 are provided to the stage 3. A material of the lifting pins 41 may be, for example, a ceramic material (e.g., alumina (Al₂O₃)), quartz, or the like. The lower end of each lifting pin 41 is attached to a supporting plate 42. The supporting plate 42 is coupled to a lifting mechanism 44 provided outside the processing chamber 2 via a lifting shaft 43.

The lifting mechanism 44 is disposed, for example, below the exhaust chamber 21. A bellow 45 is provided between an opening 21a formed in the bottom surface of the exhaust chamber 21 and the lifting mechanism 44. The opening 21a is an opening for the lifting shaft 43. The supporting plate 42 may have a shape that allows the supporting plate 42 to move up and down without interfering with the support member 31 of the stage 3. The lifting pins 41 are configured to be lifted and lowered between the upper side and lower side of the upper surface 3a of the stage 3 by the lifting mechanism 44. In other words, the lifting pins 41 are configured so that the lifting pins 41 can protrude from the upper surface 3a of the stage 3.

A gas supply 5 is provided on a ceiling wall 27 of the processing chamber 2 via an insulating member 28. The gas supply 5 constitutes an upper electrode and faces the lower electrode 33. An RF-power source 51 is electrically coupled to the gas supply 5 via an impedance matching device 52. A frequency band of the RF-power source 51 is, for example, from 450 kHz to 2.45 GHZ. The RF-power source 51 supplies RF power to the gas supply 5 so that an RF electric field is generated between the gas supply 5 and the lower electrode 33. The gas supply 5 includes a hollow gas diffusion chamber 53. A large number of holes 54 are evenly arranged in the bottom surface of the gas diffusion chamber 53. The holes 54 are holes for dispersing and supplying a process gas into the processing chamber 2. A heating mechanism 55 is embedded in the gas supply 5, for example, above the gas diffusion chamber 53. A power supply (not illustrated) supplies power to the heating mechanism 55 according to a control signal transmitted from the controller 9 to heat the heating mechanism 55 to a set temperature.

A gas supply path 6 is provided in the gas diffusion chamber 53. The gas supply path 6 communicates with the gas diffusion chamber 53. A gas source 61 is coupled to the upstream side of the gas supply path 6 via a gas line 62. The gas source 61 includes, for example, sources of various process gases, a mass flow controller, and a valve (all of which are not illustrated). The process gases include gases used in the below-described plasma processing method. The process gases are fed from the gas source 61 to the gas diffusion chamber 53 through the gas line 62.

The plasma processing apparatus 1 includes the controller 9. The controller 9 is, for example, a computer, and includes a processor, such as a central processing unit (CPU), and one or more storage devices, such as a random access memory (RAM), a read only memory (ROM), an auxiliary storage device, and the like. The CPU operates based on a program stored in the ROM or the auxiliary storage device, and controls the operations of the plasma processing apparatus 1. The controller 9 may be disposed inside or outside the plasma processing apparatus 1. In the case where the controller 9 is disposed outside the plasma processing apparatus 1, the controller 9 can control the plasma processing apparatus by a wired or wireless communication method, or the like.

Although the plasma processing apparatus 1 has been described through the example of the plasma processing apparatus that forms a capacitively coupled plasma (CCP), the present disclosure is not limited to the above example. The plasma processing apparatus may be a plasma processing apparatus that generates a plasma by remote plasma using high frequency waves (RF or VHF), or microwaves (MW). The plasma processing apparatus that generates a plasma by remote plasma may be a plasma processing apparatus that generates a plasma in a processing chamber in which a substrate W is accommodated using a remote plasma technique, or a plasma processing apparatus that supplies a plasma, which is remotely generated, to a processing chamber in which a substrate W is accommodated.

### [Plasma Processing Method]

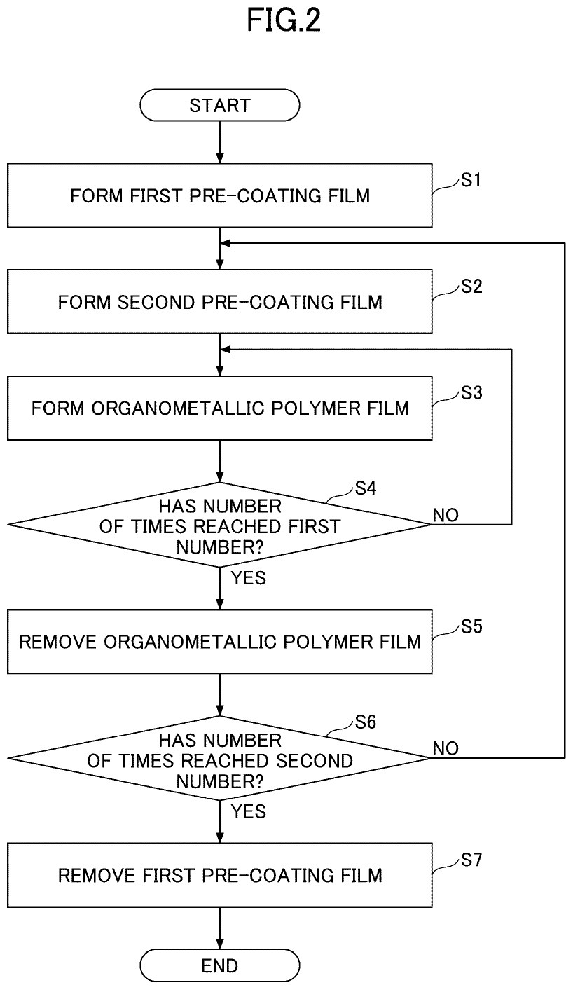

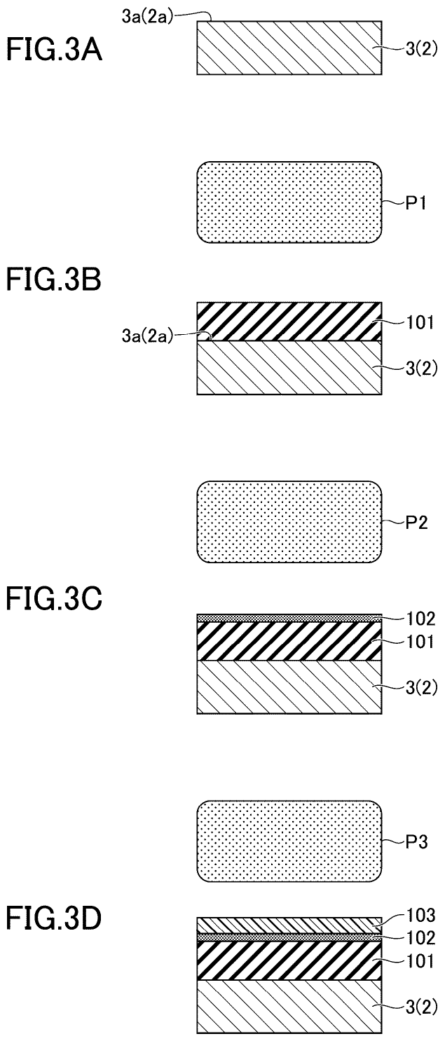

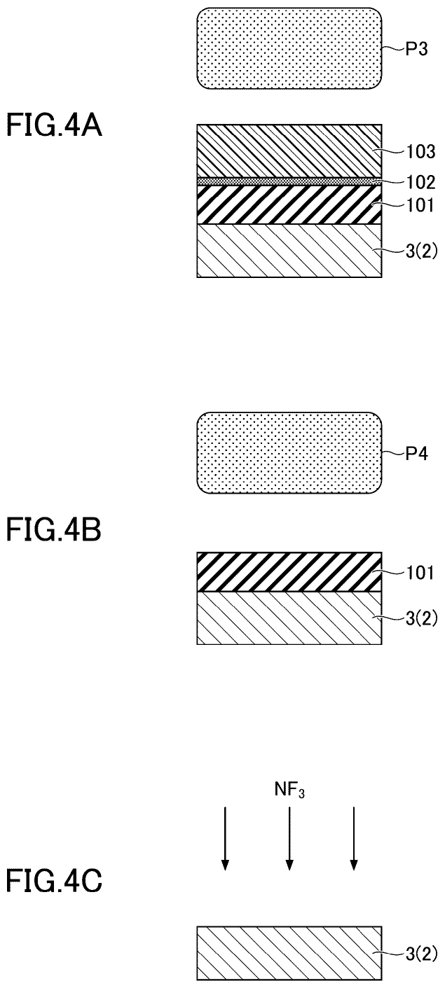

A plasma processing method executed by the plasma processing apparatus 1 will be described with reference to FIGS. 2 to 5. FIG. 2 is a flowchart illustrating the plasma processing method according to one embodiment. FIGS. 3A to 3D and FIGS. 4A to 4C are cross-sectional views illustrating the plasma processing method according to the present embodiment.

The plasma processing method illustrated in FIG. 2 is automatically executed when the controller 9 controls the operation of each constituent component of the plasma processing apparatus 1. In the description below, an assumption is given that a film is not deposited on an inner surface of the processing chamber 2 of the plasma processing apparatus 1 at a start of the plasma processing method. The inner surface of the processing chamber 2 includes an inner wall surface 2a of the processing chamber 2, and an upper surface 3a of the stage 3. The present embodiment will be described through an example in which the upper surface 3a of the stage 3 is described as the inner surface of the processing chamber 2 as illustrated in FIG. 3A, but the same or similar embodiment as the upper surface 3a of the stage 3 may be applied to another part of the inner surface of the processing chamber 2 (e.g., the inner wall surface 2a of the processing chamber 2).

The plasma processing method illustrated in FIG. 2 includes step S1, step S2, step S3, step S4, step S5, step S6, and step S7.

### (Step S1)

In step S1, a first pre-coating film 101 is formed on the upper surface 3a of the stage 3 (the inner wall surface 2a of the processing chamber 2) as illustrated in FIG. 3B. The first pre-coating film 101 contributes to inhibition of scattering of metal atoms included in the stage 3 or the processing chamber 2, such as aluminum (Al), during removal of the organometallic polymer film 103 in step S5. Since the first pre-coating film 101 is provided, metal atoms are less likely to be mixed into an organometallic polymer film 103.

In the present embodiment, the controller 9 controls the gas source 61 to supply a first film-forming gas from the gas supply 5 to the processing chamber 2 through the holes 54. The first film-forming gas includes a silicon-containing gas and a nitrogen-containing gas. Moreover, the controller 9 controls the RF-power source 51 to supply RF power to the gas supply 5. Thus, the first film-forming gas is formed into a plasma P1 in the processing chamber 2, thereby depositing a silicon nitride film on the upper surface 3a of the stage 3. The silicon nitride film is one example of the first pre-coating film 101. The first pre-coating film 101 may be a silicon oxide film. In the case of the silicon oxide film, an oxygen-containing gas is used instead of the nitrogen-containing gas. Step S1 is performed, for example, in the state in which a substrate W is not placed in the recess 32 of the stage 3.

The silicon-containing gas includes, for example, at least one selected from the group consisting of an aminosilane-based gas, a hydrogenated silicon gas, a halogen-containing silicon gas, and an organic silicon-based gas. As the aminosilane-based gas, for example, di(isopropylamino) silane (DIPAS), tris(dimethylamino) silane (3DMAS), or bis(t-butylamino) silane (BTBAS) can be used. As the hydrogenated silicon gas, for example, SiH₄, Si₂H₆, Si₃H₈, or Si₄H₁₀ can be used. As the halogen-containing gas, for example, SiF₄, SiHF₃, SiH₂F₂, SiH₃F, SiCl₄, SiHCl₃, SiH₂Cl₂, SiH₃Cl, Si₂Cl₆, SiBr₄, SiHBr₃, SiH₂Br₂, or SiH₃Br can be used. As the organic silicon-containing gas, for example, tetraethoxysilane (TEOS), tetramethoxysilane (TMOS), or dimethyldimethoxysilane (DMDMOS) can be used.

The nitrogen-containing gas includes, for example, at least one selected from the group consisting of N₂, NH₃, N₂H₂, N₂H₄, and CH₃(NH)NH₂.

The oxygen-containing gas includes, for example, at least one selected from the group consisting of O₂, O₃, H₂O, and N₂O.

### (Step S2)

In step S2, a second pre-coating film 102 is formed on the first pre-coating film 101 as illustrated in FIG. 3C. The second pre-coating film 102 contributes to reduction in diffusion of metal atoms included in an organometallic polymer film 103 formed in step S3 into the first pre-coating film 101. Since the second pre-coating film 102 is provided, the residue of the first pre-coating film 101 is not likely to remain when the first pre-coating film 101 is removed in step S7.

In the present embodiment, the controller 9 controls the gas source 61 to supply a second film-forming gas from the gas supply 5 to the processing chamber 2 via the holes 54. The second film-forming gas includes a carbon-containing gas. In addition, the controller 9 controls the RF-power source 51 to supply RF power to the gas supply 5. Thus, the second film-forming gas is formed into a plasma P2 in the processing chamber 2, thereby depositing a carbon film on the first pre-coating film 101. The carbon film is one example of the second pre-coating film 102. Step S2 is performed, for example, in the state in which a substrate W is not placed in the recess 32 of the stage 3.

The carbon-containing gas includes, for example, at least one selected from the group consisting of a fluorocarbon gas, a hydrofluorocarbon gas, and a hydrocarbon gas. As the fluorocarbon gas, for example, CF₄, C₂F₂, C₂F₄, C₃F₈, C₄F₆, C₄F₈, or C₅F₈ can be used. As the hydrofluorocarbon gas, for example, CHF₃, CH₂F₂, CH₃F, C₂HF₅, C₂H₂F₄, C₂H₃F₃, C₂H₄F₂, C₃HF₇, C₃H₂F₂, C₃H₂F₆, C₃H₂F₄, C₃H₃F₅, C₄H₅F₅, C₄H₂F₆, C₅H₂F₁₀, C—C₅H₃F₇, or C₃H₂F₄ can be used. As the hydrocarbon gas, for example, CH₄, C₂H₂, C₂H₄, C₂H₆, C₃H₆, C₃H₈, or C₄H₁₀ can be used.

### (Step S3)

In step S3, an organometallic polymer film 103 is formed on the second pre-coating film 102 as illustrated in FIG. 3D. Step S3 may include formation of the organometallic polymer film 103 on a substrate W serving as a processing target. The organometallic polymer film 103 includes metal atoms (M), carbon atoms (C), and hydrogen atoms (H). The metal atoms include, for example, at least one selected from the group consisting of hafnium (Hf), aluminum (Al), tin (Sn), zirconium (Zr), and titanium (Ti). The organometallic polymer film 103 may further include nitrogen atoms (N). The organometallic polymer film 103 may further include oxygen atoms (O).

In the present embodiment, the controller 9 controls a transporting device (not illustrated) to transfer the substrate W serving as a processing target into the processing chamber 2 of the plasma processing apparatus 1 to place the substrate W in a recess 32 of the stage 3. Moreover, the controller 9 controls the gas source 61 to supply a third film-forming gas from the gas supply 5 to the processing chamber 2 through the holes 54. The third film-forming gas includes an organometallic precursor gas, a hydrocarbon gas, and a carrier gas. Further, the controller 9 controls the RF-power source 51 to supply RF power to the gas supply 5. Thus, the third film-forming gas is formed into a plasma P3 in the processing chamber 2 to induce a polymerization reaction of the plasma P3, thereby depositing an organometallic polymer film 103 on the second pre-coating film 102.

The organometallic precursor gas may include metal atoms, carbon atoms, and hydrogen atoms. The metal atoms include, for example, at least one selected from the group consisting of hafnium, aluminum, tin, zirconium, and titanium. The organometallic precursor gas may further include nitrogen atoms. The organometallic precursor gas may further include oxygen atoms. As the organometallic precursor gas, for example, Hf((NCH₃)₂)₄, Hf(OC₄H₉)₄, Zr((N(CH₂)₂)₄, Sn(CH₃)₄, Sn(C₄H₉)₂(OC₄H₉)₂, Sn(NCH₃)₄, Or Al(CH₃)₄ can be used. As the hydrocarbon gas, for example, CH₄, C₂H₂, C₂H₄, C₂H₆, C₃H₆, C₃H₈, or C₄H₁₀ can be used. As the carrier gas, for example, an argon gas (Ar) or a helium gas (He) can be used.

### (Step S4)

In step S4, whether step S3 has been performed a set number (first number) of times is determined. In the case where the number of times step S3 performed has reached the first number (YES in step S4), the process proceeds to step S5. In the case where the number of times step S3 performed has not reached the first number (No in step S4), step S3 is performed again. As step S3 is repeated, a thickness of the organometallic polymer film 103 on the second pre-coating film 102 increases as illustrated in FIG. 4A. If the thickness of the organometallic polymer film 103 on the second pre-coating film 102 exceeds a threshold, the organometallic polymer film 103 is peeled off, and particles are generated. Therefore, the first number is set so that the thickness of the organometallic polymer film 103 does not exceed the threshold.

### (Step S5)

In step S5, the organometallic polymer film 103 deposited on the upper surface 3a of the stage 3 (the inner wall surface 2a of the processing chamber 2) is removed as illustrated in FIG. 4B.

In the present embodiment, the controller 9 controls the temperature controller 34 to adjust a temperature of the stage 3 to a set temperature. The set temperature may be 80° C. or higher and 200° C. or lower. Moreover, the controller 9 controls the pressure regulator 23 to adjust the pressure inside the processing chamber 2 to a set pressure. The set pressure may be 0.1 Torr (13.3 Pa) or greater and 10 Torr (1.33 kPa) or less. Further, the controller 9 controls the gas source 61 to supply a first etching gas from the gas supply 5 to the processing chamber 2 through the holes 54. The first etching gas includes a hydrogen gas, a carbon-containing gas, and a nitrogen-containing gas. Further, the controller 9 controls the RF-power source 51 to supply RF power to the gas supply 5. Thus, the first etching gas is formed into a plasma P4 in the processing chamber 2. The organometallic polymer film 103 reacts with the plasma P4 to be vaporized so that the organometallic polymer film 103 is removed from the upper surface 3a of the stage 3 (the inner wall surface 2a of the processing chamber 2). The plasma P4 may include CH radicals and NH radicals. The CH radicals and NH radicals have a long lifetime. Therefore, the organometallic polymer film 103 deposited in a position far from the plasma P4, such as the inner wall surface 2a of the processing chamber 2, can be efficiently removed. The nitrogen atoms (N) and carbon atoms (C) have a low ionization energy. Therefore, acceleration of hydrogen ions to high energy can be inhibited. As a result, damage in the surface of the gas supply 5 can be minimized, which reduces metal contamination. When the organometallic polymer film 103 is removed, the second pre-coating film 102 may be removed without removing the first pre-coating film 101 formed on the upper surface 3a of the stage 3 (the inner wall surface 2a of the processing chamber 2). The first etching gas may further include an inert gas. As the inert gas, for example, an argon gas or a helium gas can be used.

The carbon-containing gas may be at least one gas selected from the gases listed as the carbon-containing gas in step S2. The nitrogen-containing gas may be at least one gas selected from the gases listed as the nitrogen-containing gas in step S1.

As an example, a case where the organometallic polymer film 103 including an Sn—CₓH_{y} bond, an Sn—OH bond, and an Sn—OCH_{y} bond is removed using the first etching gas including a hydrogen gas (H₂), a methane gas (CH₄), and an ammonia gas (NH₃) will be described. The methane gas is one example of the carbon-containing gas, and the ammonia gas is one example of the nitrogen-containing gas. In the Sn—CₓH_{y} bond and the Sn—OCₓH_{y} bond, each of x and y is an integer of 1 or greater.

In this case, the reactions represented by the following formulae (1) and (2) are caused in the plasma P4, thereby generating HN(CH₃)₂ that is a stable amino-structure species. HN(CH₃)₂ is a gas.

NH₃+2CH₄→CNₓ↓+HN(CH₃)₂+2H₂ Formula (1)

CNₓ+H₂→HN(CH₃)_{2↑} Formula (2)

At the surface of the organometallic polymer film 103, the reactions represented by the following formulae (3), (4), and (5) are caused to decompose the organometallic polymer film 103, thereby generating metal amino-structure species, such as Sn—N(CH₃)₂, Sn—N(CH₃)₂, Sn—N(CH₃)₂, and the like. Since the metal amino-structure species are stable, the metal amino-structure species are less likely to re-deposit on the reaction surface. Therefore, the organometallic polymer film 103 can be efficiently removed. Moreover, the carbon atoms (C) are vaporized in the form of CₓH_{y}+1, CₓH_{y}OH, or the like. Thus, deposition of carbon atoms (C) on the reaction surface can be minimized.

Sn—CₓH_{y}+HN(CH₃)₂→Sn—N(CH₃)₂+CₓH_{y+1↑} Formula (3)

Sn—OH+HN(CH₃)₂→Sn—N(CH₃)₂+H₂O_{↑} Formula (4)

Sn—OCH_{y}+HN(CH₃)₂→Sn—N(CH₃)₂+CₓH_{y}OH₅₂ Formula (5)

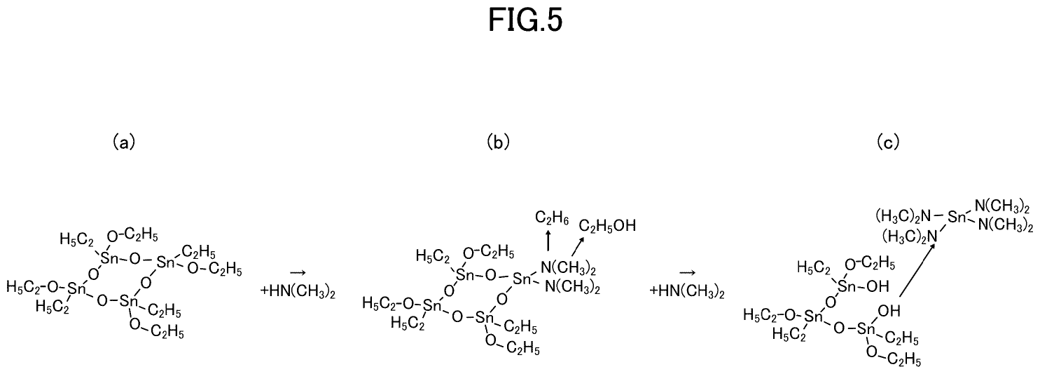

FIG. 5 is a diagram illustrating one example of the reaction scheme of the organometallic polymer film 103. As illustrated in (a) of FIG. 5, the organometallic polymer film 103 includes tin (Sn) as metal atoms, and includes an Sn—C₂H₅ bond and an Sn—OC₂H₅ bond. When the plasma P4 is formed from the first etching gas including a hydrogen gas (H₂), a methane gas (CH₄), and an ammonia gas (NH₃), the organometallic polymer film 103 reacts with HN(CH₃)₂ included in the plasma P4. Thus, the Sn—C₂H₅ bond and the Sn—OC₂H₅ bond included in the organometallic polymer film 103 are replaced with Sn—N(CH₃)₂, thereby generating C₂H₆ and C₂H₅OH, as illustrated in (b) of FIG. 5. As the reaction progresses further, the Sn—O bond is replaced with Sn—N(CH₃)₂ so that part of the organometallic polymer film 103 is removed as Sn[N(CH₃)₂]₄, as illustrated in (c) of FIG. 5.

Moreover, the first etching gas may include, for example, a halogen gas. The halogen gas may be one selected from the group consisting of F₂, Cl₂, Br₂, I₂, HF, HCl, HBr, HI, and BCl₃. The plasma of the first etching gas (e.g., NH₃/CH₄/H₂) to which a halogen gas is added can form a metal halogen structure in addition to a metal amino-structure species, thereby improving the decomposition efficiency, particularly, in a portion having a high oxygen content. Thus, the etching efficiency is increased, and the residue of the metal oxide can be reduced.

### (Step S6)

In step S6, whether or not a series of step S2 to step S5 is performed a set number (second number) of times is determined. In the case where the series of step S2 to step S5 has been repeated the second number of times (YES in step S6), the process proceeds to step S7. In the case where the number of times the series of step S2 to step S5 repeated has not reached the second number (NO in step S6), the process returns to step S2, and the series of step S2 to step S5 is performed again. The second number of times is set, for example, according to at least one selected from the group consisting of conditions for forming a second pre-coating film 102, conditions for forming an organometallic polymer film 103, and conditions for removing the organometallic polymer film 103.

### (Step S7)

In step S7, the first pre-coating film 101 formed on the upper surface 3a of the stage 3 (the inner wall surface 2a of the processing chamber 2) is removed, as illustrated in FIG. 4C.

In the present embodiment, the controller 9 controls the gas source 61 to supply a second etching gas from the gas supply 5 to the processing chamber 2 through the holes 54. The second etching gas includes a fluorine-containing gas. Thus, the first pre-coating film 101 is removed from the upper surface 3a of the stage 3 (the inner wall surface 2a of the processing chamber 2). The second etching gas may further include an inert gas. As the inert gas, for example, an argon gas or a helium gas can be used. The fluorine-containing gas is, for example, a nitrogen trifluoride gas (NF₃).

As described above, according to the present embodiment, the first etching gas is supplied to the processing chamber 2 to generate the plasma P4, and the organometallic polymer film 103 is allowed to react with the plasma P4 so that the organometallic polymer film 103 is vaporized and removed. The first etching gas includes a hydrogen gas, a carbon-containing gas, and a nitrogen-containing gas. In this case, the organometallic polymer film 103 can be efficiently removed from the inside of the processing chamber 2.

After step S5, a step of supplying an inert gas to the processing chamber 2 without supplying the first etching gas to the processing chamber 2 to thereby purge the processing chamber 2 with the inert gas may be performed. Moreover, after step S5, a step of exhausting the processing chamber 2 without supplying a gas to the processing chamber 2 may be performed. Further, step S5 and the step of purging may be alternately repeated, step S5 and the step of exhausting may be alternately repeated, or step S5, the step of purging, and the step of exhausting may be repeated in this order. Thus, the vaporized organometallic polymer film 103 can be removed more efficiently.

Moreover, the pressure inside the processing chamber 2 may be changed during the course of step S5. For example, step S5 may include a step of maintaining the pressure inside the processing chamber 2 at a first pressure, and a step of maintaining the pressure inside the processing chamber 2 at a second pressure that is higher than the first pressure. In this case, the organometallic polymer film 103 deposited in various positions of the inner surface of the processing chamber 2 can be efficiently removed.

### [Experiment Results]

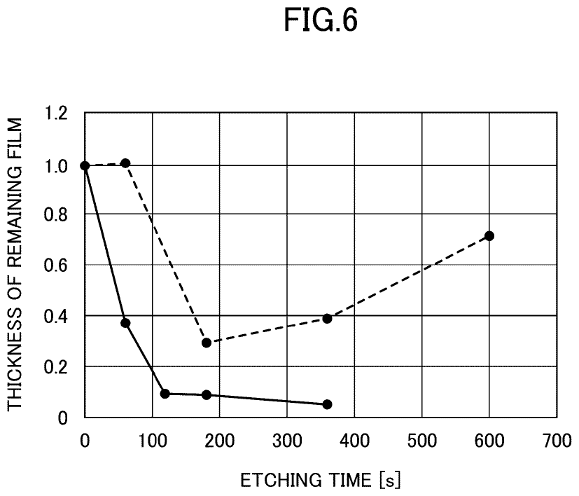

FIG. 6 is a graph depicting the gas type dependency of the etching rate of the organometallic polymer film 103. In FIG. 6, the horizontal axis represents an etching time [seconds], and the vertical axis represents a thickness of the remaining organometallic polymer film 103. The thickness of the remaining film is represented by a relative value when the thickness of the organometallic polymer film 103 at the etching time of 0 seconds is determined as 1. The solid line in FIG. 6 indicates the etching rate of the organometallic polymer film 103 when the organometallic polymer film 103 is exposed to a plasma formed from an etching gas including a hydrogen gas, a methane gas, and an ammonia gas (referred to as a “first plasma” hereinafter). The dashed line in FIG. 6 indicates the etching rate of the organometallic polymer film 103 when the organometallic polymer film 103 is exposed to a plasma formed from an etching gas that is free from an ammonia gas and includes a hydrogen gas and a methane gas (referred to as a “second plasma” hereinafter).

As demonstrated in FIG. 6, when the organometallic polymer film 103 is exposed to the first plasma, the thickness of the remaining film is 0.1 or less at the time when 120 seconds has elapsed, and an increase in the thickness of the remaining film with the elapse of time is not observed. Conversely, when the organometallic polymer film 103 is exposed to the second plasma, the thickness of the remaining film is approximately 0.3 at the time when 180 second has elapsed, and the thickness of the remaining film increases after 180 seconds. It is considered from the above results that re-deposition of a reaction product, which is generated by a reaction between the plasma and the organometallic polymer film 103, to the reaction surface can be reduced by exposing the organometallic polymer film 103 to the plasma formed from the etching gas including the hydrogen gas, the carbon-containing gas, and the nitrogen-containing gas. As a result, the organometallic polymer film 103 can be efficiently removed.

The embodiments disclosed are merely examples in all respects and should not be construed as being limited thereto. The embodiments may be modified and improved in various forms, for example by partially omitting, replacing, or the like, without departing from the scope and spirit of the appended claims.

What is claimed is:

1. A method of removing an organometallic polymer film deposited inside a processing chamber, the method comprising:
a) supplying a first etching gas to the processing chamber, and forming the first etching gas into a plasma; and
b) allowing the organometallic polymer film to react with the plasma to vaporize and remove the organometallic polymer film,
wherein the first etching gas includes a hydrogen gas, a carbon-containing gas, and a nitrogen-containing gas.

2. The method of removing the organometallic polymer film, according to claim 1,
wherein a) includes generating an amino-structure species from the first etching gas, and
b) includes generating a metal amino-structure species that includes a metal atom included in the organometallic polymer film.

3. The method of removing the organometallic polymer film, according to claim 1,
wherein the plasma includes CH radicals and NH radicals.

4. The method of removing the organometallic polymer film, according to claim 1,
wherein the organometallic polymer film includes metal atoms, carbon atoms, and hydrogen atoms.

5. The method of removing the organometallic polymer film, according to claim 4,
wherein the metal atoms include at least one selected from a group consisting of hafnium, aluminum, tin, zirconium, and titanium.

6. The method of removing the organometallic polymer film, according to claim 1,
wherein the organometallic polymer film includes nitrogen atoms, oxygen atoms, or both.

7. The method of removing the organometallic polymer film, according to claim 1,
wherein the carbon-containing gas is a hydrocarbon gas.

8. The method of removing the organometallic polymer film, according to claim 1,
wherein the nitrogen-containing gas is a nitrogen gas or an ammonia gas.

9. The method of removing the organometallic polymer film, according to claim 1,
wherein the first etching gas further includes an inert gas.

10. The method of removing the organometallic polymer film, according to claim 1,
wherein the first etching gas further includes a halogen gas.

11. The method of removing the organometallic polymer film, according to claim 10,
wherein the halogen gas includes at least one selected from a group consisting of F₂, Cl₂, Br₂, I₂, HF, HCl, HBr, HI, and BCl₃.

12. A plasma processing method comprising:
a) forming a first pre-coating film, which includes a silicon nitride film, a silicon oxide film, or both, in a processing chamber of a plasma processing apparatus;
b) forming a second pre-coating film, which includes a carbon film, on the first pre-coating film in the processing chamber;
c) forming an organometallic polymer film on the second pre-coating film in the processing chamber;
d) after c), supplying a first etching gas to the processing chamber, and forming the first etching gas into a plasma; and
e) after d), allowing the organometallic polymer film to react with the plasma to vaporize and remove the organometallic polymer film,
wherein the first etching gas includes a hydrogen gas, a carbon-containing gas, and a nitrogen-containing gas.

13. The plasma processing method according to claim 12,
wherein e) includes removing the second pre-coating film.

14. The plasma processing method according to claim 12, further comprising:
f) repeating b), c), d), and e) in this order.

15. The plasma processing method according to claim 14, further comprising:
g) after f), supplying a second etching gas to the processing chamber to remove the first pre-coating film,
wherein the second etching gas includes a fluorine-containing gas.

16. A plasma processing apparatus for forming an organometallic polymer film, the plasma processing apparatus comprising:
a processing chamber;
a gas supply configured to supply a first etching gas to the processing chamber, the first etching gas including a hydrogen gas, a carbon-containing gas, and a nitrogen-containing gas;
one or more storage devices; and
a processor coupled to the one or more storage devices and configured to:
supply the first etching gas from the gas supply to the processing chamber, in which the organometallic polymer film is formed, and form the first etching gas into a plasma; and
allow the organometallic polymer film to react with the plasma to vaporize and remove the organometallic polymer film.
